(19) United States
(12) Patent Application Publication
(10) Pub. No.: US 2025/0212648 A1
(43) Pub. Date: Jun. 26, 2025

(54) DISPLAY PANEL, METHOD FOR MANUFACTURING THE SAME, AND DISPLAY DEVICE

(71) Applicants: HEFEI VISIONOX TECHNOLOGY CO., LTD., Hefei (CN); KUNSHAN GO-VISIONOX OPTO-ELECTRONICS CO., LTD., Kunshan (CN)

(72) Inventors: Bo RAO, Hefei (CN); Chung-Chun LEE, Hefei (CN); Xiaoxi SUN, Hefei (CN); Yuan YAO, Hefei (CN); Liusong NI, Hefei (CN)

(73) Assignees: HEFEI VISIONOX TECHNOLOGY CO., LTD., Hefei (CN); KUNSHAN GO-VISIONOX OPTO-ELECTRONICS CO., LTD., Kunshan (CN)

(21) Appl. No.: 18/650,396

(22) Filed: Apr. 30, 2024

(30) Foreign Application Priority Data
Dec. 23, 2023 (CN) 202311799532.1

(51) Int. Cl. H10K 59/40; G06F 3/044; H10K 59/122; H10K 59/80; H10K 102/00

(52) U.S. Cl. CPC H10K 59/40; H10K 59/122; H10K 59/873; G06F 3/044; G06F 2203/04103; H10K 2102/351

(57) ABSTRACT

A display panel includes a substrate. A partition structure is disposed on the substrate and defines multiple partitioned openings. The partition structure includes multiple first ring grooves and is divided, by the first ring grooves, into a first structure and a second structure located in the first ring grooves. A light-emitting functional layer includes multiple light-emitting structures disposed in the partitioned openings. The insulating layer covers a side of the partition structure away from the substrate. A touch layer is disposed on a side of the insulating layer away from the partition structure and includes multiple first touch structures disposed at intervals along a longitudinal direction and multiple second touch structures disposed at intervals along a lateral direction. The first touch structure and the second touch structure are independent of each other and form a mutual capacitance by the bridging of the second structure.

### CROSS-REFERENCE TO RELATED APPLICATIONS

The present application claims priority to Chinese patent application No. 2023117995321, filed on Dec. 23, 2023, the entire contents of which are incorporated herein by reference.

### TECHNICAL FIELD

The present disclosure relates to the field of display technologies, particularly to a display panel, a method for manufacturing the same, and a display device having the same.

### BACKGROUND

OLED (Organic Light-emitting Diode) display panels are one of the hot topics in the field of display panel research today. Compared to liquid crystal display panels, OLED display panels have advantages such as low power consumption, low cost, self-emission, wide viewing angle, fast response speed, etc.

However, current OLED display panels have lots of problems such as high cost and relatively large thickness when integrating the touch function in an On-cell manner.

### SUMMARY

According to a first aspect, an embodiment of the present disclosure provides a display panel, including: a substrate; a partition structure disposed on the substrate and defining a plurality of partitioned openings, the partition structure being provided with a plurality of first ring grooves, the partition structure being divided into a first structure and a second structure by the plurality of first ring grooves, the second structure being located in the plurality of first ring grooves; a light-emitting functional layer including a plurality of light-emitting structures, the plurality of light-emitting structures being disposed in the partitioned openings; an insulating layer covering a side of the partition structure away from the substrate; and a touch layer disposed on a side of the insulating layer away from the partition structure, the touch layer including a plurality of first touch structures disposed at intervals along a first direction and a plurality of second touch structures disposed at intervals along a second direction intersecting with the first direction, the first touch structures and the second touch structures being independent of each other and forming a bridge through the second structure.

According to the display panel provided in this embodiment of the present disclosure, the partition structure is divided into the first structure and the second structure disposed in the first ring grooves by the first ring grooves. The first touch structures and the second touch structures in the touch layer that are independent of each other form mutual capacitance through the bridging of the second structure, so that one mask is used to prepare the partition structure and one mask is used to prepare the touch layer. The mutual capacitance between the first touch structures and the second touch structures can be realized only by using the second structure. In addition, the touch layer is disposed on the insulating layer, so that an In-cell mutual capacitance touch control can be realized. The foregoing display panel has a relatively low manufacturing cost and is relatively thin.

According to a second aspect, an embodiment of the present disclosure provides a display panel, including: a substrate; a partition structure disposed on the substrate and defining a plurality of partitioned openings, the partition structure being provided with a plurality of first ring grooves, and the partition structure being divided into a first structure and second structure by the plurality of first ring grooves, the second structure is located in the plurality of first ring grooves; a light-emitting functional layer including a plurality of light-emitting structures, the plurality of light-emitting structures being disposed in the partitioned openings; an insulating layer covering a side of the partition structure away from the substrate; and a touch layer disposed on a side of the insulating layer away from the partition structure, the touch layer including at least two first touch structures that extend along a second direction and are disposed at intervals and a second touch structure that extends along a first direction, orthographic projections of the at least two first touch structures that are disposed at intervals along the second direction on the substrate and an orthographic projection of the second structure on the substrate are connected to from a straight line, and the orthographic projections of the at least two first touch structures intersects an orthographic projection of the second touch structure on the substrate.

According to a third aspect, an embodiment of the present disclosure provides a method for manufacturing a display panel, including: providing a substrate; forming a partition structure on the substrate, the partition structure defining a plurality of partitioned openings, the partition structure being provided with a plurality of first ring grooves, the partition structure being divided into a first structure and a second structure by the plurality of first ring grooves, and the second structure is located in the plurality of first ring grooves; forming a plurality of light-emitting structures and an insulating layer on the substrate, the plurality of light-emitting structures being disposed in the partitioned openings, and the insulating layer covers a side of the partition structure away from the substrate; forming a touch layer on the substrate, the touch layer being disposed on a side of the insulating layer away from the partition structure, and the touch layer including a plurality of first touch structures disposed at intervals along a first direction and a plurality of second touch structures disposed at intervals along a second direction that intersects with the first direction, and the first touch structures and the second touch structures are independent of each other and form a bridge through the second structure.

According to the method for manufacturing a display panel provided in the embodiment of the present disclosure, the partition structure is divided into the first structure and the second structure disposed in the first ring grooves by the first ring grooves. The first touch structures and the second touch structures in the touch layer that are independent of each other form mutual capacitance through the bridging of the second structure, so that one mask is used to prepare the partition structure and one mask is used to prepare the touch layer. The mutual capacitance between the first touch structures and the second touch structures can be realized only by using the second structure. In addition, the touch layer is disposed on the insulating layer, so that an In-cell mutual capacitance touch control can be realized. The foregoing display panel has a relatively low manufacturing cost and is relatively thin.

According to a fourth aspect, an embodiment of the present disclosure provides a display device, including the display panel as described in any one of the embodiments of the first aspect and the second aspect.

According to the display device provided in this embodiment of the present disclosure, the partition structure is divided into the first structure and the second structure disposed in the first ring grooves by the first ring grooves. The first touch structures and the second touch structures in the touch layer that are independent of each other form mutual capacitance through the bridging of the second structure, so that one mask is used to prepare the partition structure and one mask is used to prepare the touch layer. The mutual capacitance between the first touch structures and the second touch structures can be realized only by using the second structure. In addition, the touch layer is disposed on the insulating layer, so that an In-cell mutual capacitance touch control can be realized. The foregoing display panel has a relatively low manufacturing cost and is relatively thin.

These and other objects, advantages, purposes and features will become apparent upon review of the following specification in conjunction with the drawings.

### BRIEF DESCRIPTION OF THE DRAWINGS

In order to describe the technical solutions in the embodiments of the present disclosure or the conventional technologies more clearly, a brief introduction will be made to the accompanying drawings that are required for describing the embodiments or the conventional technologies. Apparently, the accompanying drawings described below show merely some embodiments of the present disclosure, and a person of ordinary skill in the art may derive other drawings from these accompanying drawings without creative efforts.

FIG. 1 is a schematic top view of a display panel according to an embodiment of the present disclosure.

FIG. 2 is a schematic cross-sectional view taken along line A-A of FIG. 1.

FIG. 3 is a schematic cross-sectional view taken along line B-B of FIG. 1.

FIG. 4 is a schematic top view of a display panel according to another embodiment of the present disclosure.

FIG. 5 is a schematic cross-section view taken along line C-C of FIG. 4.

FIG. 6 is a flowchart of a method for manufacturing a display panel according to an embodiment of the present disclosure.

FIG. 7 is a schematic view of a display device according to an embodiment of the present disclosure.

### REFERENCE NUMERALS

01. display device;
10. display panel; Y. first direction; X. second direction; Z: third direction;
100. substrate. 110. array substrate;
200. partition structure; 210. partitioned opening; 220. first ring groove; 230. first structure;
240. second structure;
300. light-emitting structure; 310. first light-emitting structure; 320. second light-emitting structure; 330. third light-emitting structure;
400. insulating layer; 410. first via;
500. touch layer; 510. first touch structure; 520. second touch structure;
610. first encapsulation layer; 620. second encapsulation layer; 630. third encapsulation layer.

### DETAILED DESCRIPTION OF THE EMBODIMENTS

In order to facilitate understanding of the present disclosure, the present disclosure will be described more fully below with reference to related drawings. Embodiments of the present disclosure are presented in the drawings. However, the disclosure may be implemented in many different forms and is not limited to the embodiments described herein. Conversely, these embodiments are provided to make the disclosure more thorough and comprehensive.

It should be noted that when a component is described to be “fixed to” another component, it may be directly on the other component or there may also be an intermedium component. When a component is considered to be “connected to” another component, it may be directly connected to the other component or there may also be an intermediate component. The terms “vertical”, “horizontal”, “left”, “right”, and similar expressions are used herein for illustrative purposes only.

In this specification, space-related terms such as “upper” and “lower” are defined with reference to the accompanying drawings. Therefore, it will be understood that “upper” and “lower” can be used interchangeably. It will be understood that when a layer is referred to as being “on” another layer, it may be directly formed on the other layer or there may also be an intermediate layer. Accordingly, it will be understood that when the layer is referred to as “directly on” another layer, there is no intermediate layer inserted therebetween.

In the accompanying drawings, the dimensions of the layers and regions may be exaggerated for clarity. It should be understood that when a layer or component is referred to as being “on” another layer or substrate, the layer or component may be directly on the other layer or substrate, or there may be one or more intermediate layers. In addition, it should also be understood that when a layer is referred to as being “between” two layers, it may be the only layer between the two layers, or there may be one or more intermediate layers. In addition, the same reference numerals always denote the same components.

Hereinafter, although terms such as “first”, “second”, etc. may be used to describe various components, these components are not limited to the above terms. The above terms are only used to distinguish one component from another. It should also be understood that the expressions used in the singular form include the plural form unless the expression in the singular form has a distinct meaning in the context. In addition, in the following embodiments, it should also be understood that the terms “include” and/or “have” as used herein indicate the presence of the stated feature or component, but do not exclude the existence of addition of one or more other features or components.

In the following embodiments, when a layer, region, or component is referred to as being “connected”, it may be construed as the layer, region, or component being connected not only directly but also through other components placed therebetween. For example, when a layer, region, component, or the like is referred to as being connected or electrically connected, the layer, region, component, or the like may not only be directly connected or electrically connected, but also be connected or electrically connected through another layer, region, component, or the like placed therebetween.

The term “and/or” used in the application document includes any combination and all combinations of one or more associated listed items. When an expression such as “at least one . . . ” is located after a list of components (elements), it modifies the whole list of components (elements) rather than individual components (elements) in the list.

Unless otherwise defined, all technical and scientific terms used herein have the same meaning as those commonly understood by those skilled in the art to which the present disclosure belongs. The terms used in the specification of the present disclosure are merely intended to describe specific embodiments and are not intended to limit the present disclosure. The term “and/or” as used herein includes any and all combinations of one or more associated listed items.

It should also be understood that the term “include/comprise” or “have”, etc. indicates the existence of the stated features, entireties, steps, operations, components, portions, or combinations thereof, but does not exclude the possibility of the existence or addition of one or more additional features, entireties, steps, operations, components, portions, or combinations thereof.

It should also be understood that when interpreting the components, although not explicitly described, the components are interpreted to include an error range, which should be within an acceptable range of deviation for a specific value as determined by a person skilled in the art. For example, terms such as “about”, “approximately”, or “substantially” may mean it is within one or more standard deviations and is not limited herein.

In addition, in the specification, the phrase “schematic diagram of plane distribution” refers to the drawings when the target portion is observed from above, and the phrase “schematic cross-section view” refers to the drawings when the cross section taken by cutting the target portion vertically is observed from the side.

In addition, the accompanying drawings are not drawn in a scale of 1:1. The relative dimensions of the components are drawn in the accompanying drawings only by way of example and are not necessarily drawn in a real scale.

As described in the background, a partition structure in a conventional OLED display panel serves as an evaporation limit and an encapsulation limit for light-emitting structures. During evaporation, light-emitting layers and the cathodes of the light-emitting structures are separated by the partition structure, and the cathodes are electrically connected through the partition structure, so that the OLED display panel is easy to manufacture and has a reduced thickness. However, the touch layer of the conventional OLED display panel integrates the touch function in an On-cell manner, which requires at least four masks for etching operations during manufacturing, resulting in technical problems such as high cost and large stack thickness, which causes a relatively high cost and a relatively large thickness of the OLED display panel.

To address the foregoing problems, embodiments of the present disclosure provide a display panel, a method for manufacturing the same, and a display device using the same. First ring grooves are defined in a partition structure so as to divide the partition structure into a first structure and second structures, and the second structures are located in the first ring grooves. The first touch structure and the second touch structure are independent of each other and form a mutual capacitance through the bridge of the second structure. In this way, compared to the conventional On-cell manner for integrating the touch function using four masks, in the embodiments of the present disclosure, one mask for preparing the partition structure is improved, and then an In-cell mutual capacitance touch control can be realized by using one more mask, so that the manufacturing cost is relatively low and the thickness of the product is relatively thin.

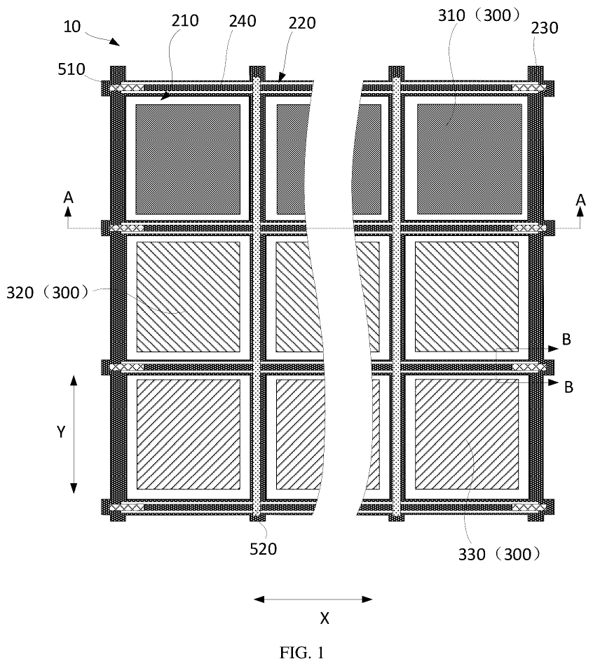

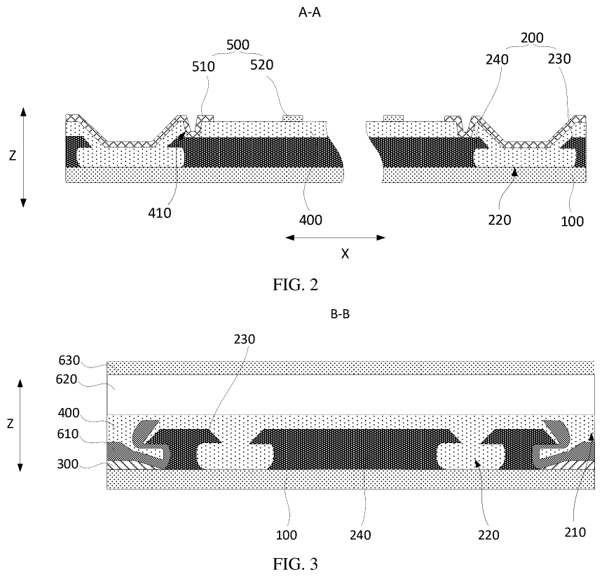

Referring to FIG. 1, FIG. 2, and FIG. 3, a display panel 10 according to a first embodiment includes a substrate 100, a partition structure 200, a light-emitting function layer, an insulating layer 400, and a touch layer 500. The partition structure 200 is disposed on the substrate 100, and a plurality of partitioned openings 210 are defined by the partition structure 200. A plurality of first ring grooves 220 are defined in the partition structure 200, the partition structure 200 is divided into a first structure 230 and second structures 240 by the plurality of first ring grooves 220, and the second structures 240 are located in the plurality of first ring grooves 220. The light-emitting function layer includes a plurality of light-emitting structures 300. The plurality of light-emitting structures 300 are disposed in the plurality of partitioned openings 210 in one-to-one correspondence. The insulating layer 400 covers a side of the partition structure 200 away from the substrate 100. The touch layer 500 is disposed on a side of the insulating layer 400 away from the partition structure 200. The touch layer 500 includes a plurality of first touch structures 510 and a plurality of second touch structures 520. The plurality of first touch structures 510 are disposed at intervals along a first direction Y, the plurality of second touch structures 520 are disposed at intervals along a second direction X, and the first direction Y intersects the second direction X. The first touch structures 510 and the second touch structures 520 are independent of each other, and the first touch structures 510 and the second touch structures 520 form a mutual capacitance through a bridge of the second structures 240.

It should be noted that the substrate 100 may be an array substrate 110. The array substrate 110 includes an array driver circuit. The partition structure 200 may be grid-shaped, multiple ring-like structures, or the like. Adjacent light-emitting structures 300 are separated by the partition structure 200. The plurality of light-emitting structures 300 may include a plurality of first light-emitting structures 310 that emit red light, a plurality of second light-emitting structures 320 that emit blue light, and a plurality of third light-emitting structures 330 that emit green light. The first light-emitting structures 310, the second light-emitting structures 320, and the third light-emitting structures 330 are alternately arranged. Each light-emitting structure 300 includes an anode, a light-emitting layer, and a cathode. The anode and the cathode may be made of at least one of an indium tin oxide or an indium zinc oxide. The light-emitting layer may be an organic layer. An array driving circuit on the substrate 100 is electrically connected to the anode of each of the light-emitting structures and is configured to control a drive voltage applied between the anode and the cathode of each of the light-emitting structures, so that the light-emitting structures 300 emit light and the display panel 10 performs the display function.

The insulating layer 400 may be made of carbon oxide, nitrogen oxide, boron oxide, or the like, which is deposited using Chemical Vapor Deposition (CVD). The touch layer 500 may be made of metal, metal oxide, mixture containing metals, or the like. In some embodiments, one of the first touch structure 510 and the second touch structure 520 forms a sensing touch channel, and the other one of the first touch structure 510 and the second touch structure 520 forms a drive touch channel. To facilitate subsequent description, the first direction Y is defined as the longitudinal direction, the second direction X is defined as the transverse direction, and the first direction Y is perpendicular to the second direction X. A third direction Z is perpendicular to the substrate 100, and the third direction Z is perpendicular to the first direction Y and the second direction X. It should be understood that the protection scope of the present disclosure is not limited thereto. In other embodiments, the first direction Y and the second direction X may also be interchanged.

According to the aforementioned display panel 10, the partition structure 200 is divided into the first structure 230 and the second structures 240 by the first ring grooves 220, and the second structures are located in the first ring grooves 220. The first touch structure 510 and the second touch structure 520 of the touch layer 500 that are independent of each other form a mutual capacitance through the bridge of the second structure 240. Therefore, one mask is used for preparing the partition structure 200, and one mask is used for preparing the touch layer 500. The mutual capacitance between the first touch structure 510 and the second touch structure 520 can be realized only by using the second structure 240. Additionally, the touch layer 500 is disposed on the insulating layer 400, so that an In-cell mutual capacitance touch control can be realized, and the aforementioned display panel 10 can be manufactured at a low cost and with a thin thickness.

In the embodiments of the present disclosure, the partition structure 200 is divided into the first structure 230 that separates adjacent light-emitting structures 300 and the second structures 240 that serve as the bridge for forming the mutual capacitance between the first touch structures 510 and the second touch structures 520, such that the display panel 10 has reduced stacked layers and is relatively thin. In addition, by simply making adaptive adjustments to the mask for preparing the partition structure 200, the touch layer 500 can be prepared by a single mask, with reduced manufacturing processes and low manufacturing cost.

In an embodiment, referring to FIG. 1, FIG. 2, and FIG. 3, the second structures 240 are located inside the first structures 230, and the second structures 240 and the first structure 230 are spaced apart by the first ring grooves 220, such that the partitioned openings 210 are defined by the first structure 230, and the partitioned openings 210 and the first ring grooves 220 are spaced apart.

In an embodiment, the second structure 240 and the first structure 230 are insulated from each other to prevent the second structure 240 and the first structure 230 from being affected by each other.

In an embodiment, the second structure 240 extends along the second direction X and is disposed between two light-emitting structures 300 that are adjacent along the first direction Y, such that the plurality of first touch structures 510 respectively extending above the second structures 240 are disposed at intervals along the first direction Y.

In this way, by limiting the specific positions of the second structures 240 and the first structure 230, the first ring grooves 220 will not affect the partitioned openings 210, and the second structures 240 configured to achieve the electrical connection of the first touch structures 510 after bridging do not affect the partition effect of the first structure 230 on adjacent light-emitting structures 300. In addition, the above position setting facilitates the setting of the partition structure 200.

In an embodiment, referring to FIG. 1, an orthographic projection of the second structure 240 in the second direction X covers at least a gap between two light-emitting structures 300 that are adjacent along the second direction X, such that the size of the second structure 240 in the second direction X is no less than the size of the first structure 230 between two light-emitting structures 300 that are adjacent along the second direction X.

In an embodiment, the length of the second structure 240 in the second direction X may be greater than the length of one light-emitting structure 300, and the length of the second structure 240 in the second direction X may also be greater than the total length of the plurality of light-emitting structures 300, so as to adapt to different dimension forms of the second structure 240.

In an embodiment, the plurality of second structures 240 are disposed at intervals along the first direction Y, such that there is only one second structure 240 in the second direction X. There are two first touch structures 510 in the second direction X, and the two first touch structures 510 are electrically connected after being bridged by the second structure 240.

In an embodiment, a part of the second structures 240 are arranged at intervals along the first direction Y, and another part of the second structures 240 are arranged at intervals along the second direction X, so that there are a plurality of the second structures 240 in the second direction X. A plurality of first touch structures 510 extend in the second direction X, and each two of the first touch structures 510 are electrically connected after being bridged by the second structures 240, thus achieving the electrical connection of all the first touch structures 510 in the second direction X.

In an embodiment, an orthographic projection of the second structure 240 in the second direction X intersects an orthographic projection of the second touch structure 520 in the second direction X, such that the second touch structure 520 are arranged above the second structure 240, thereby achieving the mutual capacitance between the first touch structure 510 and the second touch structure 520 through bridging.

In this way, by limiting the position relationship and the dimension relationship between the second structures 240 and adjacent light-emitting structures 300 in the second direction X, the second structures 240 does not affect the definition of the partitioned openings 210 by the partition structure 200, and adjacent light-emitting structures 300 are still separated by the first structure 230. The first touch structures 510 are arranged by utilizing the second structures 240 disposed between adjacent light-emitting structures 300 distributed along the first direction Y. The second touch structures 520 are arranged by utilizing the first structure 230 and second structures 240 that are disposed between adjacent light-emitting structures 300 distributed in the second direction X. Therefore, the light-emitting function layer and the touch control layer 500 can make full use of the partition structure 200.

In an embodiment, referring to FIG. 1, the length of the first structure 230 in the first direction Y is greater than a sum of lengths of the plurality of light-emitting structures 300 in the first direction Y, so that the first structure 230 can separate the plurality of light-emitting structures 300, respectively.

In an embodiment, the length of the first structure 230 in the first direction Y is greater than the length of the light-emitting function layer, so that the first structure 230 is a grid structure, and the first structure 230 can separate all of the light-emitting structures 300 in the first direction Y, respectively.

In this way, by limiting the dimension relationship between the first structure 230 and the light-emitting structure 300 in the first direction Y, the setting manner of the partitioned opening 210 in the first direction Y can be determined, which facilitates the formation of the partitioned opening 210 and prevents the introduction of the first ring groove 220 from affecting the partition function of the partition structure 200.

In an embodiment, two first touch structures 510 are disposed at intervals along the second direction X above the first structure 230, and the two first touch structures 510 extend above the second structure 240. The two first touch structures 510 are electrically connected to the second structure 240 to form a bridge, such that the two first touch structures 510 are electrically connected after being bridged by the second structure 240.

In an embodiment, in the second direction X, the number of the second structures 240 is less than the number of the first touch structures 510, so that both ends of the second structure 240 along the second direction X can be configured to carry the first touch structure 510, which makes the structure simpler and easy to set.

In an embodiment, in the second direction X, one second structure 240 and two first touch structures 510 are provided. In this case, the two first touch structures 510 are located at both ends of the insulating layer 400 along the second direction X, so as to further simplify the setting of the first touch structure 510 and the second structure 240.

In an embodiment, in the second direction X, the number of the second structures 240 is N that is greater than 1, and the number of the first touch structures 510 is N+1. This relationship enables a correspondence design of one mask used to prepare the partition structure 200 and another mask used to prepare the touch layer 500, thus facilitating the correspondence setting of the second structure 240 and the first touch structure 510.

In this way, by limiting that each second structure 240 has two first touch structures 510 located thereon and limiting the relative position relationship between the first touch structure 510 and the partition structure 200, a bridging connection between the plurality of first touch structures 510 can be realized conveniently and reliably.

In an embodiment, referring to FIG. 1 and FIG. 2, the second touch structures 520 extend above the second structures 240 along the first direction Y, so as to facilitate the setting of the second touch structures 520.

In an embodiment, in the second direction X, the second touch structures 520 above the same second structures 240 are located between the first touch structures 510, so as to facilitate the relative setting of the second touch structures 520 and the first touch structures 510. In addition, the second touch structures 520 and the first touch structures 510 on the same second structure 240 are spaced apart.

In an embodiment, the first ring grooves 220 extend along the second direction X, and the second touch structures 520 extend above the first structure 230, such that the plurality of second structures 240 are spaced apart along the first direction Y, and the first structure 230 is located between these second structures 240. The second touch structures 520 extend above the first structure 230, so that the second touch structures 520 span the first ring grooves 220 and cover the second structures 240 and the first structure 230, so as to ensure the continuity of the second touch structure 520 in the first direction Y.

In this way, the plurality of second touch structures 520, the plurality of first touch structures 510, and the plurality of second structures 240 form a grid structure, and each intersection point of the grid structure corresponds to a touch structure extending along the second direction X, a second structure 240, and a first touch structure 510 extending along the first direction Y, so that a unique touch position can be determined, facilitating the realization of the mutual capacitance between the first touch structures 510 and the second touch structures 520 by bridging, and the reliability and accuracy of the mutual capacitance between the first touch structures 510 and the second touch structures 520 by bridging are high.

Referring to FIG. 2, in an embodiment, the first touch structures 510 extend above an end of the second structure 240 and are electrically connected above the end of the second structure 240 to form the bridge, such that the first touch structures 510 span the first ring grooves 220 and cover the first structure 230 and the second structures 240. The first touch structure 510 is electrically connected to the second structure 240 after bridging to realize signal transmission. In a specific setting, the area of the first touch structure 510 above the end of the second structure 240 is at least sufficient to ensure the electrical connection.

In an embodiment, an orthographic projection of the second structure 240 in the second direction X does not exceed an orthographic projection of the light-emitting function layer in the second direction X, so that there is enough space in the second direction X to arrange the first ring groove 220, thus ensuring that the areas at both ends of the first structure 230 in the second direction X are suitable for setting the first touch structure 510, thereby improving the reliability of the setting of the first touch structure 510.

In an embodiment, in the edge region of the partition structure 200 in the second direction X, the orthographic projection of the second structure 240 in the second direction X intersects the orthographic projections of the partitioned openings 210 in the second direction X, such that the second structure 240 can carry the second touch structure 520 located between the two adjacent light-emitting structures 300 at the most edge. The second structure 240 has a large size and can accommodate a relatively large number of second touch structures 520, thus increasing the touch accuracy of the display panel 10.

In this way, by limiting the first touch structure 510 to be located above the end of the second structure 240 and limiting the first touch structure 510 to be electrically connected to the end of the second structure 240, more area is preserved for the arrangement of the second touch structures 520, ensuring a large area of the second structure 240 for accommodating the second touch structures 520, which facilitates the arrangement of the second touch structures 520.

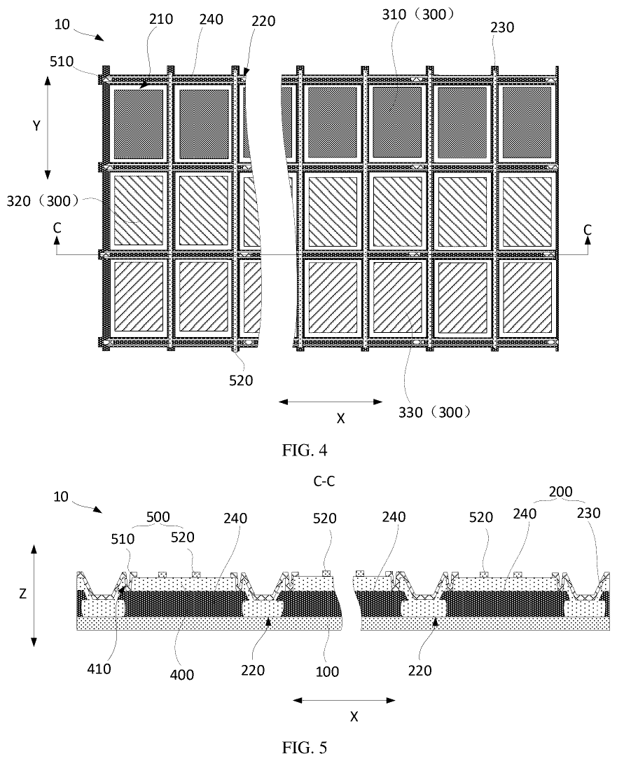

Referring to FIG. 4 and FIG. 5, in an embodiment, at least one first ring groove 220 extends in the second direction X. In a specific setting, the number of first ring grooves 220 corresponding to the first structures 230 may be the same, so as to facilitate the setting of the first ring grooves 220. The number of the first ring grooves 220 corresponding to the first structures 230 may also be different, so as to adapt to different display panels 10.

In an embodiment, one first ring groove 220 extends in the second direction X, facilitating the setting of the first ring groove 220, thereby making the structure of the partition structure 200 simple and stable.

In an embodiment, a plurality of first ring grooves 220 are disposed at intervals along the second direction X, thus facilitating the manufacturing of the partition structure 200 by one mask, and improving the structural accuracy and reliability of the mask.

In an embodiment, at least one first ring groove 220 extends to both edge regions of the partition structure 200 in the second direction X, so that in the second direction X, the first ring grooves 220 at the edge extend to both edge regions of the partition structure 200 in the second direction X, and the second structure 240 has a relatively large size in the second direction X.

In this way, by limiting the number of the first ring grooves 220 in the second direction X, the first ring grooves 220 are evenly provided in the partition structure 200 along the second direction X, facilitating the setting of the first ring grooves 220.

Referring to FIG. 2 and FIG. 5, in an embodiment, the second structures 240 include a conductive material. The insulating layer 400 defines a plurality of first vias 410 positioned above the second structures 240. Each of the first vias 410 exposes a part of the second structure 240. The first touch structure 510 is in contact with the second structure 240 exposed by the first via 410 to form the bridge, so as to realize the electrical connection between the first touch structure 510 and the second structure 240.

In an embodiment, the second structures 240 are made of metal, which has a low resistance. The material of the second structures 240 may be the same as that of the touch layer 500.

In an embodiment, the second structure 240 may be made of a material selected from the group consisting of copper, silver, gold, and any combination thereof. It should be understood that the material of the second structure 240 is not limited hereto and may be other materials that meet the requirements, such as molybdenum, aluminum, cobalt, or any combination thereof.

In this way, by limiting the second structure 240 as a conductive structure and enabling the first touch structure 510 and the second structure 240 to be in contact with each other through the first via 410 in the insulating layer 400, the electrical connection between the first touch structure 510 and the second structure 240 can be conveniently achieved, which is easy to prepare and has low cost.

Referring to FIG. 2 and FIG. 5, in an embodiment, cathodes of adjacent light-emitting structures 300 are electrically connected through the first structure 230 to provide a power signal, so as to realize a uniform control of the cathodes of all the light-emitting structures 300. The first touch structures 510 are electrically connected through the second structure 240 to provide a touch signal. Therefore, independent control of the cathodes of adjacent light-emitting structures 300 and the first touch structures 510 is achieved.

In an embodiment, the display panel 10 further includes an IC. Wiring of the touch layer 500 extends to the IC through a side bezel of the display panel 10. The second structure 240 is electrically connected to the IC, and the second touch structure is electrically connected to the IC, such that the first touch structure 510 and the second touch structure 520 are controlled by the IC, respectively, thereby achieving the electrical connection between the IC and the first touch structure 510 and reducing the product thickness.

In this way, the first structure 230 provides an electrical signal for the cathode of the light-emitting structure 300, the IC provides an electrical signal for the first touch structure 510 through the second structure 240, and the IC provides an electrical signal for the second touch structure 520. In addition, the IC controls the first touch structure 510 and the second touch structure 520 to work independently, so that the touch layer 500 does not require performing time division multiplexing on the cathode signal of the light-emitting structure 300, facilitating the implementation of the touch function.

In the embodiments of the present disclosure, since the first structure 230, the second structure 240, and the second touch structure 520 are independently controlled, the independent control of the cathode of the light-emitting structure 300, the first touch structure 510, and the second touch structure 520 can be achieved. Compared to the conventional technology in which the touch layer performs time division multiplexing on the cathode signal, thereby leading to the touch function and the display function being controlled in a time-division manner through time coordination, the control logic provided in the present disclosure is relatively simple and easy to realize.

Referring to FIG. 2 and FIG. 5, in an embodiment, an orthographic projection of the upper end portion of the first structure 230 away from the substrate 100 on the substrate 100 covers an orthographic projection of the lower end portion of the first structure 230 adjacent to the substrate 100 on the substrate 100. In a specific setting, the first structure 230 includes a partition portion and a blocking portion. The blocking portion is located above the partition portion. The blocking portion is formed by the upper end portion of the first structure 230, and the partition portion is formed by the lower end portion of the first structure 230. The partition portion and the blocking portion may be integrally formed or may be prepared by multiple stacking.

In an embodiment, a cross-section of the side of the first structure 230 away from the first ring groove 220 along a third direction Z perpendicular to the substrate 100 may be a T-shape or an inverted trapezoidal shape, and it may also be a combination of a T-shape and an inverted trapezoidal shape.

In this way, the light-emitting layers of adjacent light-emitting structures 300 are separated by the lower end portion of the first structure 230, and the cathodes of adjacent light-emitting structures 300 are separated by the upper end portion of the first structure 230, such that although the first ring grooves 220 are provided in the partition structure 200, it can be ensured that the separation effect of the partition structure 200 on adjacent light-emitting structures 300 is not affected.

Referring to FIG. 2 and FIG. 5, in an embodiment, an orthographic projection of the upper end portion of the second structure 240 away from the substrate 100 on the substrate 100 covers an orthographic projection of the lower end portion of the second structure 240 adjacent to the substrate 100 on the substrate 100.

In an embodiment, a cross-section of the second structure 240 along the third direction Z perpendicular to the substrate 100 may be a T-shape or an inverted trapezoid, and it may also be a combination of a T-shape and an inverted trapezoid.

In an embodiment, in the third direction Z perpendicular to the substrate 100, the cross-section of the second structure 240 is the same as the cross-section of the first structure 230.

In this way, both the second structure 240 and the first structure 230 have the upper end portion larger than the lower end portion, so that the first structure 230 and the second structure 240 can be formed by etching using one mask. In the etching process, the first structure 230 and the second structure 240 form an undercut structure, such that the second structure 240 and the first structure 230 are prepared by one etching process.

In an embodiment, referring to FIG. 3, the display panel 10 further includes a first encapsulation layer 610 covering the light-emitting structures 300 and a sidewall of the partition structure, so as to protect the light-emitting structures 300. In a specific setting, the first encapsulation layer 610 is prepared using chemical vapor deposition (CVD).

In an embodiment, the insulating layer 400 is located on a side of the first encapsulation layer 610 away from the light-emitting structures 300, which on the one hand facilitates the setting of the insulating layer 400 and ensuring the insulating effect, on the other hand, the protection effect for the light-emitting structures 300 by the insulating layer 400 is further improved.

In this way, by providing the first encapsulation layer 610, the path for water and oxygen to enter the light-emitting structures 300 through the touch layer 500 side is cut off, which can reduce the amount of water and oxygen reaching the light-emitting structures 300, thereby improving the water and oxygen barrier capability of the display panel 10.

In an embodiment, a side of the touch layer 500 away from the insulating layer 400 is further provided with a second encapsulation layer 620 and a third encapsulation layer 630, so as to protect the touch layer 500 and further protect the light-emitting structures 300.

Referring to FIG. 1, FIG. 2, and FIG. 3, a display panel 10 according to a second embodiment includes a substrate 100, a partition structure 200, a light-emitting functional layer, an insulating layer 400, and a touch layer 500. The partition structure 200 is disposed on the substrate 100. A plurality of partitioned openings 210 are defined by the partition structure 200. The partition structure 200 is provided with a plurality of first ring grooves 220. The partition structure 200 is divided into a first structure 230 and second structures 240 by the plurality of first ring grooves 220, and the second structures 240 are located in the plurality of first ring grooves 220. The light-emitting function layer includes a plurality of light-emitting structures 300. The plurality of light-emitting structures 300 are disposed in the partitioned openings 210 in one-to-one correspondence. The insulating layer 400 covers a side of the partition structure 200 away from the substrate 100. The touch layer 500 is disposed on a side of the insulating layer 400 away from the partition structure 200. The touch layer 500 includes a plurality of first touch structures 510 and a plurality of second touch structures 520.

At least two first touch structures 510 extend along a second direction X and are disposed at intervals. The second touch structures 520 extend along a first direction Y. Orthographic projections of the at least two first touch structures 510 disposed at intervals along the second direction X on the substrate 100 and an orthographic projection of the second structure 520 on the substrate are connected to form a straight line. The orthographic projections of the at least two first touch structures 510 on the substrate intersect with an orthographic projection of the second touch structure 520 on the substrate 100.

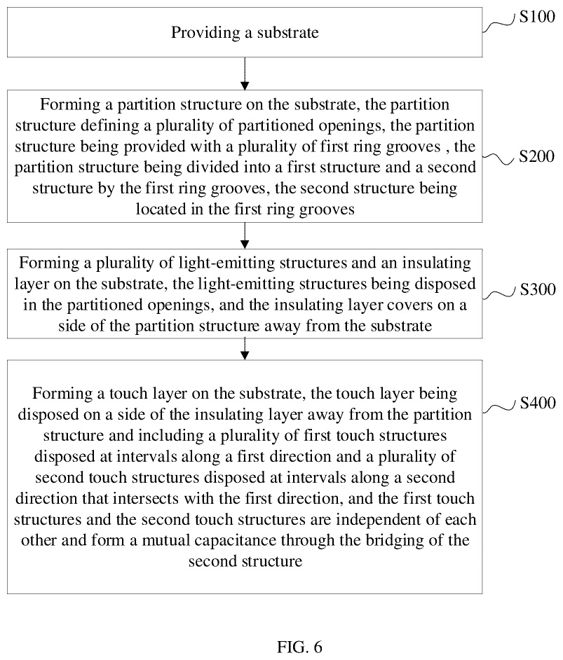

Referring to FIG. 6, a method for manufacturing the aforementioned display panel includes the following steps.

In step S100, a substrate is provided. For example, the substrate may be an array substrate.

In step S200, a partition structure is formed on the substrate. The partition structure defines a plurality of partitioned openings. The partition structure is provided with a plurality of first ring grooves. The partition structure is divided into a first structure and a second structure by the plurality of first ring grooves. The second structures are located in the plurality of first ring grooves. For example, a partition material is deposited on the substrate, and then the partition structure is etched by using one mask.

In step S300, a plurality of light-emitting structures and an insulating layer are formed on the substrate. The plurality of light-emitting structures are disposed in the partitioned openings, and the insulating layer covers a side of the partition structure away from the substrate. For example, a first conductive material layer, a light-emitting material layer, a second conductive material layer, and an insulation material layer of a whole surface may be evaporated sequentially on the whole surface, and then a plurality of first light-emitting structures and first insulating units are formed through patterning. By repeating the above manufacturing steps, the second light-emitting structures, the second insulating units, the third light-emitting structures, and the third insulating units are prepared, respectively. The first insulating units, the second insulating units, and the third insulating units constitute the insulating layer.

In step S400, a touch layer is formed on the substrate. The touch layer is disposed on a side of the insulating layer away from the partition structure. The touch layer includes a plurality of first touch structures disposed at intervals along a first direction and a plurality of second touch structures disposed at intervals along a second direction that intersects with the first direction. The first touch structures and the second touch structure are independent of each other, and the first touch structure and the second touch structure form a mutual capacitance through a bridge of the second structures. For example, a touch material is deposited on a side of the insulating layer away from the partition structure, and then the touch layer is etched by using one mask.

According to the aforementioned method for manufacturing the display panel, the partition structure is divided into the first structure and second structures by the first ring grooves, and the second structures are located in the first ring grooves. The first touch structure and the second touch structure of the touch layer that are independent of each other form a mutual capacitance through the bridge of the second structure, so that the partition structure is prepared by using one mask, and the touch layer is prepared by using one mask. The mutual capacitance between the first touch structure and the second touch structure can be realized only by using the second structures. Additionally, the touch layer is disposed on the insulating layer, so that an In-cell mutual capacitance touch control can be realized. The foregoing display panel has a relatively low manufacturing cost and is relatively thin.

It should be understood that, although steps in the flowcharts involved in the accompanying drawings are sequentially shown by instructions of arrows, these steps are not necessarily executed according to the instruction of the arrows. Unless expressly stated herein, the execution of these steps is not strictly limited to the order, and these steps may be performed in others order. In addition, at least a part of the steps in the accompanying drawings may include multiple steps or phases. These steps or phases are not necessarily performed at the same moment, but may be performed at different moments. The execution sequence of these steps or phases is not necessarily sequential, but may be performed alternately or in turn with other steps or at least a part of the steps or phases of other steps.

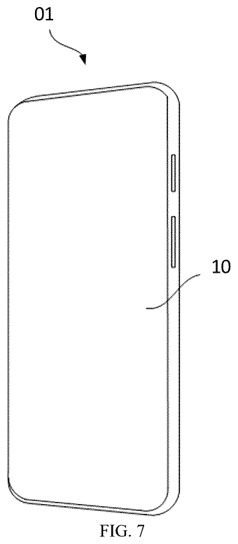

Referring to FIG. 7, embodiments of the present disclosure provide a display device 01, including the display panel 10 according to any embodiments described above.

The display device 01 may be a mobile terminal or a fixed terminal having a display panel 10, such as a mobile phone, a television, a tablet computer, a laptop computer, an Ultra-Mobile Personal Computer (UMPC), a Personal Digital Assistant (PDA), a navigation device, a smart watch, a virtual reality device, or the like.

According to the display device provided in the embodiments of the present disclosure, a partition structure is divided into a first structure and second structures by first ring grooves, and the second structures are located in the first ring grooves. A first touch structure and a second touch structure of a touch layer that are independent of each other form a mutual capacitance through the bridging of the second structures, so that one mask is used to prepare the partition structure and one mask is used to prepare the touch layer. The mutual capacitance between the first touch structure and the second touch structure can be realized only by using the second structures. In addition, the touch layer is disposed on an insulating layer, so that an In-cell mutual capacitance touch control can be realized. The foregoing display panel has a relatively low manufacturing cost and is relatively thin.

The technical features in the foregoing embodiments may be randomly combined. For concise description, not all possible combinations of the technical features in the foregoing embodiments are described. However, provided that combinations of the technical features do not conflict with each other, the combinations of the technical features should be considered as falling with the scope recorded in this specification.

The foregoing embodiments represent only several embodiments of the present disclosure, and the description thereof is relatively specific and detailed, but should not be construed as a limitation on the scope of the disclosure. It should be noted that for those skilled in the art, without departing from the concept of the present disclosure, several modifications and improvements can be made, which all fall within the protection scope of the present disclosure. Therefore, the protection scope of the present disclosure shall be subject to the appended claims.

What is claimed is:

1. A display panel, comprising:
a substrate;
a partition structure disposed on the substrate and defining a plurality of partitioned openings, the partition structure being provided with a plurality of first ring grooves, the partition structure being divided into a first structure and a second structure by the plurality of first ring grooves, the second structure being located in the plurality of first ring grooves;
a light-emitting functional layer comprising a plurality of light-emitting structures, the plurality of light-emitting structures being disposed in the partitioned openings;
an insulating layer covering a side of the partition structure away from the substrate; and
a touch layer disposed on a side of the insulating layer away from the partition structure, the touch layer comprising a plurality of first touch structures disposed at intervals along a first direction and a plurality of second touch structures disposed at intervals along a second direction intersecting with the first direction, the first touch structure and the second touch structure being independent of each other and forming a bridge through the second structure.

2. The display panel according to claim 1, wherein the second structure is located inside the first structure, and the second structure and the first structure are spaced apart by the first ring groove;
the second structure and the first structure are insulated from each other;
the second structure extends along the second direction and is disposed between two light-emitting structures that are adjacent along the first direction.

3. The display panel according to claim 2, wherein an orthographic projection of the second structure in the second direction covers at least a gap between two light-emitting structures that are adjacent along the second direction;
a length of the second structure in the second direction is greater than a length of at least one light-emitting structure;
a plurality of second structures are disposed at intervals along the first direction, and a plurality of light-emitting units are disposed therebetween;
an orthographic projection of the second structure in the second direction intersects an orthographic projection of the second touch structure in the second direction;
or a part of the plurality of second structures are arranged at intervals along the first direction, and another part of the plurality of second structures are arranged at intervals along the second direction.

4. The display panel according to claim 2, wherein a length of the first structure in the first direction is greater than a sum of lengths of the plurality of light-emitting structures in the first direction;
or the length of the first structure in the first direction is greater than a length of the light-emitting function layer.

5. The display panel according to claim 1, wherein two of the first touch structures extend along the second direction and are disposed at intervals above the first structure, the two of the first touch structures extend above the second structure and are electrically connected to the second structure to form the bridge.

6. The display panel according to claim 1, wherein in the second direction, a number of the second structures is less than a number of the first touch structures;
or in the second direction, one second structure and two first touch structures are provided;
or in the second direction, a number of the second structures is N that greater than 1, and a number of the first touch structures is N+1.

7. The display panel according to claim 6, wherein the second touch structures extend along the first direction, and at least a part of the second touch structures are disposed above the second structure;
in the second direction, the second touch structures above the same second structure are located between the first touch structures;
or the first ring grooves extend along the second direction, and the second touch structures extend above the first structure.

8. The display panel according to claim 7, wherein the plurality of first touch structures extend above an end of the second structure and are electrically connected above the end of the second structure to form the bridge;
an orthographic projection of the second structure in the second direction does not exceed an orthographic projection of the light-emitting function layer in the second direction.

9. The display panel according to claim 7, wherein at least one first ring groove extends in the second direction;
or one first ring groove extends in the second direction;
or a plurality of first ring grooves are disposed at intervals along the second direction;
the least one first ring groove extends to both edge regions of the partition structure in the second direction.

10. The display panel according to claim 1, wherein the second structure comprise a conductive material, the insulating layer defines a plurality of first vias above the second structure, each of the first vias exposes a part of the second structure, and the first touch structure is in contact with the second structure exposed by the first via to form the bridge.

11. The display panel according to claim 1, wherein the second structure is made of metal;
or the second structure is made of a material selected from the group consisting of copper, silver, gold, and any combination thereof.

12. The display panel according to claim 1, wherein cathodes of adjacent light-emitting structures are electrically connected through the first structure to provide a power signal, and the first touch structures are electrically connected through the second structure to provide a touch signal;
the display panel further comprises an IC, and wirings of the first touch structures extend to the IC through a side bezel of the display panel.

13. The display panel according to claim 1, wherein an orthographic projection of an upper end portion of the first structure away from the substrate on the substrate covers an orthographic projection of a lower end portion of the first structure adjacent to the substrate on the substrate;
or a cross-section of a side of the first structure away from the first ring groove along a third direction perpendicular to the substrate is one of a T-shape, an inverted trapezoid, or a combination thereof.

14. The display panel according to claim 13, wherein an orthographic projection of an upper end portion of the second structure away from the substrate on the substrate covers an orthographic projection of a lower end portion of the second structure adjacent to the substrate on the substrate.

15. The display panel according to claim 13, wherein a cross-section of the second structure in the third direction perpendicular to the substrate is one of a T-shape, an inverted trapezoid, or a combination thereof.

16. The display panel according to claim 13, wherein in the third direction perpendicular to the substrate, a cross-section of each second structure is the same as a cross-section of the first structure.

17. The display panel according to claim 1, further comprising a first encapsulation layer covering the light-emitting structures and a sidewall of the partition structure.

18. The display panel according to claim 17, wherein the insulating layer is located on a side of the first encapsulation layer away from the light-emitting structures;
a second encapsulation layer and a third encapsulation layer are further disposed on a side of the touch layer away from the insulating layer.

19. A display panel, comprising:
a substrate;
a partition structure disposed on the substrate and defining a plurality of partitioned openings, the partition structure being provided with a plurality of first ring grooves, and the partition structure being divided into a first structure and a second structure by the plurality of first ring grooves, the second structure being located in the plurality of first ring grooves;
a light-emitting functional layer comprising a plurality of light-emitting structures, the plurality of light-emitting structures being disposed in the partitioned openings;
an insulating layer covering a side of the partition structure away from the substrate; and
a touch layer disposed on a side of the insulating layer away from the partition structure, the touch layer comprising at least two first touch structures that extend along a second direction and are disposed at intervals and a second touch structure that extends along a first direction, wherein orthographic projections of the at least two first touch structures that are disposed at intervals along the second direction on the substrate and an orthographic projection of the second structure on the substrate are connected to from a straight line, and the orthographic projections of the at least two first touch structures intersect an orthographic projection of the second touch structure on the substrate.

20. A method for manufacturing a display panel, comprising:
providing a substrate;
forming a partition structure on the substrate, wherein the partition structure defines a plurality of partitioned openings, the partition structure is provided with a plurality of first ring grooves, the partition structure is divided into a first structure and a second structure by the plurality of first ring grooves, and the second structure is located in the plurality of first ring grooves;
forming a plurality of light-emitting structures and an insulating layer on the substrate, wherein the plurality of light-emitting structures are disposed in the partitioned openings, and the insulating layer covers a side of the partition structure away from the substrate; and
forming a touch layer on the substrate, wherein the touch layer is disposed on a side of the insulating layer away from the partition structure, the touch layer comprises a plurality of first touch structures disposed at intervals along a first direction and a plurality of second touch structures disposed at intervals along a second direction that intersects with the first direction, and the plurality of first touch structures and the plurality of second touch structures are independent of each other and form a bridge through the second structure.
